(19) United States
(12) Patent Application Publication
(10) Pub. No.: US 2010/0147376 A1
(43) Pub. Date: Jun. 17, 2010

(54) SOLAR BATTERY DEVICE, METHOD OF PRODUCING SAME, AND ELECTRONIC DEVICE

(76) Inventors: Yoshihide Iwazaki, Osaka-shi (JP); Kohji Miyata, Osaka-shi (JP); Shohnosuke Ueno, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/633,098

(22) Filed: Dec. 8, 2009

(30) Foreign Application Priority Data
Dec. 11, 2008 (JP) 2008-315753

(51) Int. Cl. H01L 31/0216; H01L 31/18

(52) U.S. Cl. 136/256; 438/72; 257/E31.119

(57) ABSTRACT

A solar battery device includes: a substrate; a plurality of solar cells on the substrate; and a surface protector on the solar cell, so as to protect a surface of the solar battery device. The surface protector has an incident surface to which light enters, and which is subjected to an anti-reflection process for preventing reflection of the light, thereby to improve power generation efficiency. The anti-reflection process for examples gives the surface protector a saw-tooth-like shape. The surface protector is made of a synthetic resin. In this way, the present invention provides a solar battery device in which reduction in the power generation efficiency due to the surface protector or the like on the surface thereof is prevented, and which has excellent transportability and applicability to portable devices.

This Nonprovisional application claims priority under 35 U.S.C. §119(a) on Patent Application No. 2008-315753 filed in Japan on Dec. 11, 2008, the entire contents of which are hereby incorporated by reference.

### TECHNICAL FIELD

The present invention relates to a solar battery device including a solar cell. More specifically, the present invention relates to a solar battery device in which power generation efficiency reduction due to a surface protector provided to a surface of the solar battery device is prevented and which has good transportability and applicability to a portable device, and the present invention further relates to a method of producing such solar battery device and to an electronic device.

### BACKGROUND ART

FIG. 5 is a cross sectional view schematically illustrating a solar battery device 110 mounted on a portable electronic device.

The solar battery device 110 includes: a support substrate 102, which is located on a housing 107 of the portable electronic device; a plurality of solar cells 101 provided on the support substrate 102; a surface protector 104 provided on the solar cell 101 and the support substrate 102 via an adhesive agent 103. The solar battery device 110 generates electricity by photovoltaic power generation, and provide the electricity to a power source (secondary battery) of the portable electronic device.

The surface protector 104 may be PET (polyethylene terephthalate) sheet, glass, or the like. For the sake of better power generation efficiency of the solar cell 101, a light incident surface of the surface protector 104 is subjected to an anti-reflection process 105 to prevent reflection of incident light. The anti-reflection process 105 gives saw-tooth-like shape to the light incident surface, as illustrated in FIG. 5. (For example, Patent Literatures 1 and 2 provided another examples of such anti-reflection process.) As an alternative of the anti-reflection process 105, an anti-reflection material (not illustrated) may be applied to the light incident surface of the surface protector 104.

### Citation List

### Patent Literature

Patent Literature 1: Japanese Patent Application Patent Literature 2: Japanese Patent Application Publication, Tokukai, No. 2004-111453 (publication date: Apr. 8, 2004)

### SUMMARY OF INVENTION

### Technical Problem

The conventional surface protector 104 such as the pet sheet, glass, or the like is adhered on the solar cell 101 and the support substrate 102 via the adhesive agent 103. The adhesive agent 103 converts the incident light passing therethrough to heat. This deteriorates the power generation efficiency of the solar cell 101.

Moreover, the need of the adhesive agent 103 gives one extra member to the solar battery device 110. Further, the need of the adhesive agent 103 results in a heavier weight per area of the solar cells 101. Moreover, the need of the adhesive agent 103 renders the solar battery device 110 poor in applicability to portable devices and in transportability.

Moreover, the production of the solar battery device 110 requires more steps because the adhesive agent 103 is necessary and the PET sheet, glass, or the like is used as the surface protector 104 and should be adhered on the solar cell 101 and the support substrate 102 after the surface protector 104 undergoes the anti-reflection process 105 or like.

The present invention was made in view of the aforementioned problems, and an object of the present invention is to provide a solar battery device, a method of producing the same, and an electronic device comprising the same, by each of which the reduction in power generation efficiency due to a surface protector or the like provided on the surface of the solar battery device is prevented, and which has or provides excellent transportability and applicability to portable devices.

### Solution to Problem

In order to attain the object, a solar battery device according to the present invention comprises: a substrate; at least one solar cell on the substrate; a surface protector on the solar cell, so as to protect a surface of the solar battery device, the surface protector being made of a synthetic resin, and having an incident surface to which light enters, and which is subjected to an anti-reflection process for preventing reflection of the light.

In order to attain the object, a method according to the present invention for producing a solar battery device, is a method comprising: (i) forming at least one solar cell on a substrate; (ii) forming a surface protector on the solar cell from a synthetic resin, the surface protector protecting a surface of the solar battery device; and (iii) performing anti-reflection process on an incident surface of the surface protector to which incident surface light enters, the anti-reflection process preventing reflection of the light, the step (ii) and step (iii) being carried out at a same time.

In these arrangement and method, the surface protector is formed from the synthetic resin. Thus, unlike the conventional art, an adhesive agent is not necessary in this arrangement and the method. Therefore, these arrangement and method can solve the conventional problems raised by the adhesive agent, such as: reduction in power generation efficiency of the solar cells; poor transportability and poor applicability to portable electronic devices due to an increase in members of the solar battery device, and a heavier weight per area of the solar cells; and an increase in the number of steps in the production. In other words, the these arrangement and method give better power generation efficiency to the solar cells, and better applicability to portable electronic devices and better transportability to the solar battery device. Further, these arrangement and method reduce the number of steps in the production of the solar battery device.

Furthermore, the anti-reflection process to the surface protector prevents reflection of incident light and allows the incident light to reach the solar cells, even if the incident light is incident on the light incident surface at an incident angle of less than 90 degrees (note that incident light can reach the solar cells with a greatest arrival ratio when its indicant angle is 90 degrees). In this way, the anti-reflection process improves the power generation efficiency of the solar battery device even if the incident light is incident on the light incident surface at an incident angle of less than 90 degrees.

Moreover, the anti-reflection process can be performed during the formation of the surface protector, because the surface protector is made from the synthetic resin. This reduces the number of the steps in the production of the solar battery device.

In order to attain the object, an electronic device according to the present invention comprises or is electrically connectable with the solar battery device, the solar battery device being located such that it is capable of receiving light.

As described above, the present invention provides a solar battery device, a method of producing the same, and an electronic device comprising the same, by each of which the reduction in power generation efficiency due to a surface protector or the like provided on the surface of the solar battery device is prevented, and which has or provides excellent transportability and applicability to portable devices.

### ADVANTAGEOUS EFFECTS OF INVENTION

A solar battery device according to the present invention comprises: a substrate; at least one solar cell on the substrate; a surface protector on the solar cell, so as to protect a surface of the solar battery device, the surface protector being made of a synthetic resin, and having an incident surface to which light enters, and which is subjected to an anti-reflection process for preventing reflection of the light.

A method according to the present invention for producing a solar battery device, is a method comprising: (i) forming at least one solar cell on a substrate; (ii) forming a surface protector on the solar cell from a synthetic resin, the surface protector protecting a surface of the solar battery device; and (iii) performing anti-reflection process on an incident surface of the surface protector to which incident surface light enters, the anti-reflection process preventing reflection of the light, the step (ii) and step (iii) being carried out at a same time.

In these arrangement and method, the surface protector is formed from the synthetic resin. Thus, unlike the conventional art, an adhesive agent is not necessary in this arrangement and the method. Therefore, these arrangement and method can solve the conventional problems raised by the adhesive agent, such as: reduction in power generation efficiency of the solar cells; poor transportability and poor applicability to portable electronic devices due to an increase in members of the solar battery device, and a heavier weight per area of the solar cells; and an increase in the number of steps in the production. In other words, the these arrangement and method give better power generation efficiency to the solar cells, and better applicability to portable electronic devices and better transportability to the solar battery device. Further, these arrangement and method reduce the number of steps in the production of the solar battery device.

Furthermore, the anti-reflection process to the surface protector prevents reflection of incident light and allows the incident light to reach the solar cells, even if the incident light is incident on the light incident surface at an incident angle of less than 90 degrees (note that incident light can reach the solar cells with a greatest arrival ratio when its indicant angle is 90 degrees). In this way, the anti-reflection process improves the power generation efficiency of the solar battery device even if the incident light is incident on the light incident surface at an incident angle of less than 90 degrees.

Moreover, the anti-reflection process can be performed during the formation of the surface protector, because the surface protector is made from the synthetic resin. This reduces the number of the steps in the production of the solar battery device.

An electronic device according to the present invention comprises or is electrically connectable with the solar battery device, the solar battery device being located such that it is capable of receiving light.

As described above, the present invention provides a solar battery device, a method of producing the same, and an electronic device comprising the same, by each of which the reduction in power generation efficiency due to a surface protector or the like provided on the surface of the solar battery device is prevented, and which has or provides excellent transportability and applicability to portable devices.

### BRIEF DESCRIPTION OF DRAWINGS

FIG. 1

FIG. 1 is a schematic cross sectional view of a solar battery device according to one embodiment of the present invention.

FIG. 2

FIG. 2 is a view illustrating matt-finishing, which is another example of the anti-reflection process.

FIG. 3

FIG. 3 is a perspective view of a portable telephone provided with (electrically connected with) the solar battery device according to the embodiment of the present invention.

FIG. 4

FIG. 4 is a perspective view of a digital still camera or digital video camera provided with (electrically connected with) the solar battery device according to the embodiment of the present invention.

FIG. 5

FIG. 5 is a cross sectional view schematically illustrating a conventional solar battery device.

### DESCRIPTION OF EMBODIMENTS

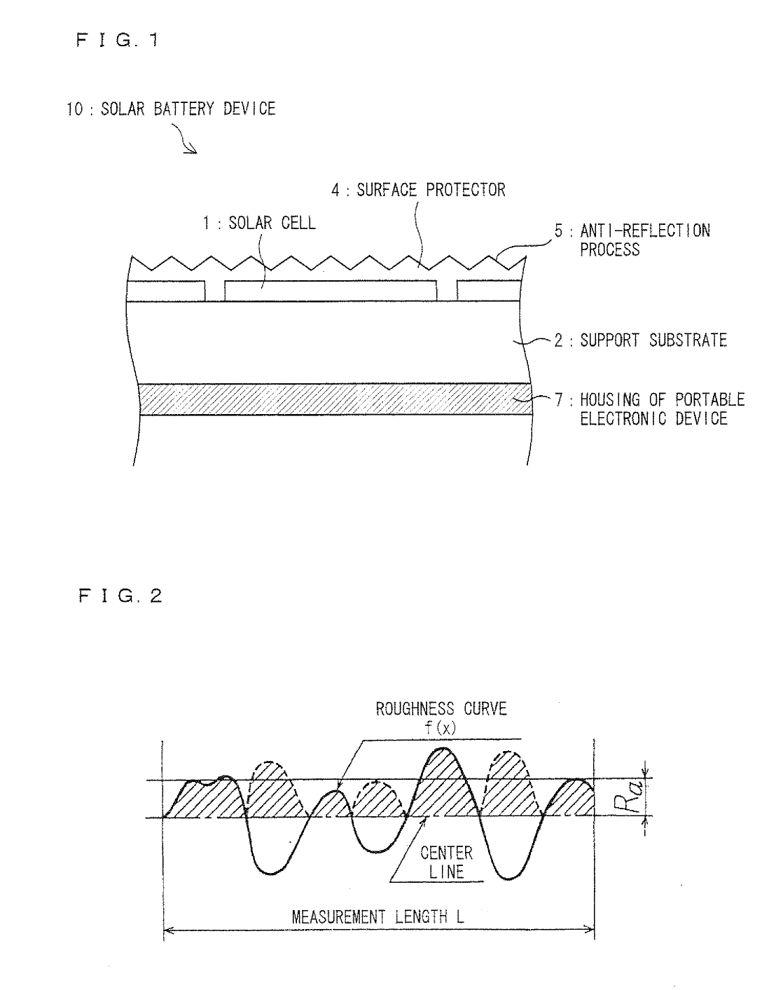

One embodiment of the present invention is described below referring to FIGS. 1 to 4.

FIG. 1 is a schematic cross sectional view of a solar battery device 10 according to one embodiment of the present invention. The solar battery device 10 is mounted on an electronic device (preferably, portable electronic device) in such a manner that the light (sun light) can reach the solar battery device 10. As an alternative, the solar battery device 10 is electrically connected (or connectable) with the electronic device in such a manner that the light (sun light) can reach the solar battery device 10. The solar battery device 10 generates power by photovoltaic power generation and supplies the power to a power source (secondary battery) of the electronic device.

The solar battery device 10 includes: a support substrate 2, which is located on a housing 7 of the portable electronic device; a plurality of solar cells 1 provided on the support substrate 2; a surface protector 4 provided on the solar cell 1 and the support substrate 2.

The solar cells 1 have a general solar cell configuration and arranged in parallel or in series so as to generate a voltage. The surface protector 4 protects a surface of the solar battery device 10. For the sake of better power generation efficiency of the solar cells 1, a light incident surface of the surface protector 4 is subjected to an anti-reflection process 5. Here, the anti-reflection process 5 gives the light incident surface a saw-tooth-like shape as illustrated in FIG. 1. The surface protector 4 is made from a synthetic resin.

The solar battery device 10 is produced by (i) forming the solar cell 1 on the support substrate 2, (ii) forming, from the synthetic resin, the surface protector 4 on the solar cell 1, and (iii) performing the anti-reflection process 5 to the light incident surface of the surface protector 4. Then, the solar battery device 10 is attached to the housing 7 of the portable electronic device via the support substrate 2.

In the present embodiment, the surface protector 4 is formed from the synthetic resin. Thus, unlike the conventional art, an adhesive agent (such as the adhesive agent 103 in FIG. 5) is not necessary in the present embodiment. Therefore, the present embodiment is free from the conventional problems raised by the adhesive agent, such as: reduction in power generation efficiency of the solar cells; poor transportability and poor applicability to portable electronic devices due to an increase in members of the solar battery device, and a heavier weight per area of the solar cells; and an increase in the number of steps in the production. In other words, the present embodiment gives better power generation efficiency to the solar cells 1, and better applicability to portable electronic devices and better transportability to the solar battery device 10. Further, the present embodiment reduces the number of steps in the production of the solar battery device 10.

Furthermore, the anti-reflection process 5 to the surface protector 4 prevents reflection of incident light and allows the incident light to reach the solar cells 1, even if the incident light is incident on the light incident surface at an incident angle of less than 90 degrees (note that incident light can reach the solar cells 1 with a greatest arrival ratio when its indicant angle is 90 degrees). In this way, the anti-reflection process 5 improves the power generation efficiency of the solar battery device 10 even if the incident light is incident on the light incident surface at an incident angle of less than 90 degrees. Especially, portable electronic devices often receive the incident light at an incident angle of less than 90 degrees because they are carried around. Thus, the solar battery device 10 is especially preferably applicable to portable devices due to this advantage thereof.

Moreover, the anti-reflection process 5 can be performed during the formation of the surface protector 4, because the surface protector 4 is made from the synthetic resin. This reduces the number of the steps in the production of the solar battery device 10.

More specifically, the surface protector 4 may be made from a thermosetting resin (e.g., epoxy resin, etc.) or a thermoplastic resin (e.g., polyethylene, polyester, etc.) containing a cross-linking agent that causes cross-linking at heat application. Such resin is solidified at a high temperature. The synthetic resin (i.e., the surface protector 4) made from such resin is difficult to deform even when a surface temperature of the solar battery device 10 becomes high, for example, in summer times.

Moreover, the synthetic resin from which the surface protector 4 is made may contain a filler by 50% by weight with respect to a total weight of the synthetic resin. The filler is made of a transparent material, such as a transparent resin. It is preferable that the filler has such a glass transition temperature that the filler will not be fluidized at a temperature at which flow molding of the synthetic resin is performed. The addition of the filler to the synthetic resin makes it easier to shape the synthetic resin. Furthermore, if the filler has such a glass transition temperature that the filler will not be fluidized at a temperature at which flow molding of the synthetic resin is performed (for example, if the filler was made of glass, polycarbonate, epoxy resin, or the like), light reflection due to the filler is difficult to occur. Thus, the use of such a filler is preferable for solar battery devices. Moreover, the addition of filler prevents thermal deformation of the synthetic resin, and expansion/shrinkage of the synthetic resin. As to the filler content, the filler is contained in the synthetic resin by 10%, 30%, or 50% by weight with respect to the total weight of the synthetic resin in general.

Moreover, the synthetic resin may be colored. The coloring may be carried out by mixing a colorant in the synthetic resin by a method generally adopted for mixing. The colorant may be power, solution, beads, or the like. This arrangement provides the solar battery device with a beautiful appearance, thereby giving a greater commercial value to the solar battery device. Instead of coloring the synthetic resin, a colored cover may be provided on the synthetic resin.

As an alternative of the saw-tooth-like shape as illustrated in FIG. 1, the anti-reflection process 5 may make matt-finishing as illustrated in FIG. 2. FIG. 2 is a view illustrating matt-finishing, which is another example of the anti-reflection process 5. It is preferable that the matt-finishing (and the saw-tooth-like shape) of the anti-reflection process 5 have a central line surface roughness (average of central line surface roughness) Ra in a range of 0.03 to 2.00 (μm). With this arrangement, the matt-finished shape and the central line surface roughness Ra of in a range of 0.03 to 2.00 μm will provide a high anti-reflection effect. The central line surface roughness Ra is, as illustrated in FIG. 2, obtained as follows: a roughness curve is folded along a central line, an area of a hatched portion in FIG. 2 is divided by a length L to obtain a quotient, which is expressed in micrometers. A central line surface roughness Ra of less than 0.03 μm means that the surface is flat, meanwhile a central line surface roughness Ra of more than 2.00 μm means the matt-finished shape has too large protrusions to cause the anti-reflection effect.

For example, the anti-reflection process 5 for the saw-tooth-like shape as illustrated in FIG. 1 may be formed by using a die with a mold or by rubbing with a rubbing material such as brush or protruded- or recessed-surfaced polishing paper. On the other hand, for example, the anti-reflection process 5 for the matt-finishing as illustrated in FIG. 2 may be carried out by using a die with a mold, or by blasting fine sands or metal particles against the surface protector 4 by means of air pressure. In case where the anti-reflection process 5 is carried out by rubbing, polishing, etc., it will produce shavings, which would possibly produce a problem such as deterioration in power generation efficiency of the solar battery device 10. Therefore, it is preferable to carry out the anti-reflection process 5 by using a die, which will not produce shavings.

Next, an exemplary application of the solar battery device 10 is described. Examples of electronic devises to which the solar battery device 10 is mounted (is electrically connected) encompass portable telephones, digital still cameras, digital video cameras, portable game machines, and global positioning system (GPS) devices (may be portable or in-vehicle (here, the term “vehicle” is not limited to automobiles but may be any kind of transportation means).

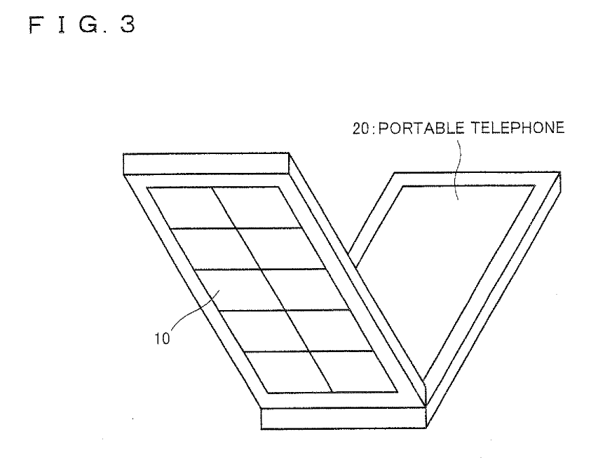

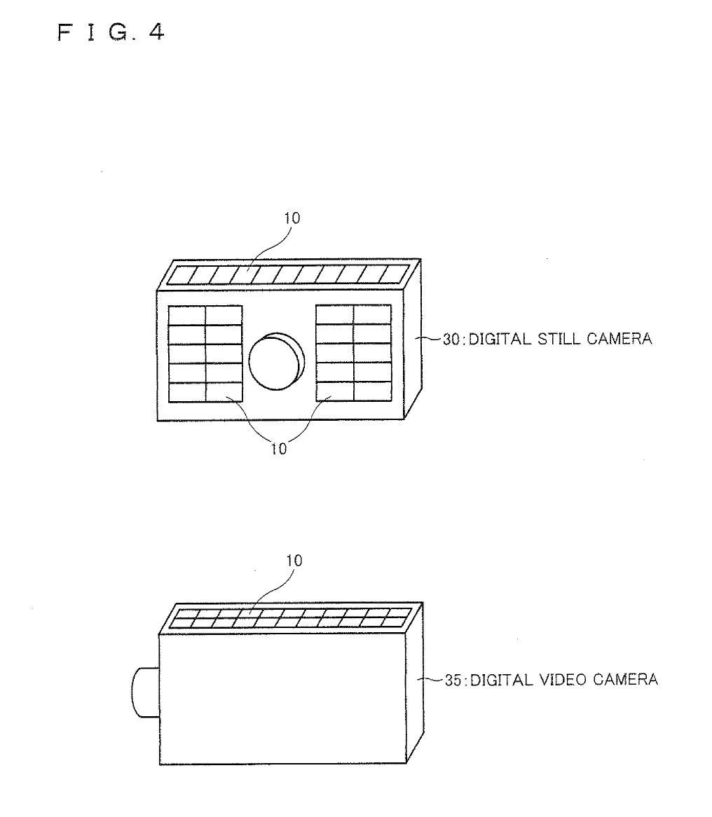

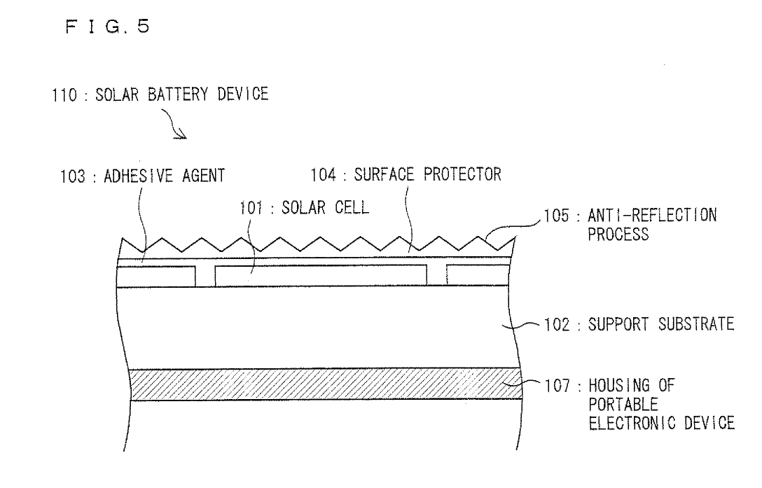

FIG. 3 is a perspective view of a portable telephone 20 provided with (electrically connected with) the solar battery device 10. FIG. 4 is a perspective view of a digital still camera 30 or digital video camera 35 provided with (electrically connected with) the solar battery device 10.

As an exemplary application, the solar battery device 10 is provided on a reverse side of the portable telephone 20. As other exemplary applications, the solar battery device 10 is provided on an upper side or a lateral side of the digital still camera 30 or digital video camera 35. Herein, these devices will not be explained on these structures in details because they are general devices. Apart from portable telephone, digital still camera, and digital video camera exemplified in illustration, portable game machines and GPS devices may be provided with the solar battery device 10 on their front side, reverse side, upper side or lateral side.

### SUMMARY OF EMBODIMENTS

A solar battery device 10 according to the present embodiment comprises: a support substrate 2; at least one solar cell 1 on the support substrate 2; a surface protector 4 on the solar cell 1, so as to protect a surface of the solar battery device 10, the surface protector 4 being made of a synthetic resin, and having an incident surface to which light enters, and which is subjected to an anti-reflection process 5 for preventing reflection of the light.

A method according to the present embodiment is a method for producing a solar battery device 10, the method comprising: (i) forming at least one solar cell 1 on a support substrate 2; (ii) forming a surface protector 4 on the solar cell 1 from a synthetic resin, the surface protector 4 protecting a surface of the solar battery device 10; and (iii) performing anti-reflection process 5 on an incident surface of the surface protector 4 to which incident surface light enters, the anti-reflection process 5 preventing reflection of the light,

the step (ii) and step being carried out at a same time.

In these arrangement and method, the surface protector 4 is formed from the synthetic resin. Thus, unlike the conventional art, an adhesive agent is not necessary in this arrangement and the method. Therefore, these arrangement and method can solve the conventional problems raised by the adhesive agent, such as: reduction in power generation efficiency of the solar cells; poor transportability and poor applicability to portable electronic devices due to an increase in members of the solar battery device, and a heavier weight per area of the solar cells; and an increase in the number of steps in the production. In other words, the these arrangement and method give better power generation efficiency to the solar cells, and better applicability to portable electronic devices and better transportability to the solar battery device. Further, these arrangement and method reduce the number of steps in the production of the solar battery device.

Furthermore, the anti-reflection process 5 to the surface protector 4 prevents reflection of incident light and allows the incident light to reach the solar cells 1, even if the incident light is incident on the light incident surface at an incident angle of less than 90 degrees (note that incident light can reach the solar cells 1 with a greatest arrival ratio when its indicant angle is 90 degrees). In this way, the anti-reflection process 5 improves the power generation efficiency of the solar battery device 10 even if the incident light is incident on the light incident surface at an incident angle of less than 90 degrees.

Moreover, the anti-reflection process 5 can be performed during the formation of the surface protector 4, because the surface protector 4 is made from the synthetic resin. This reduces the number of the steps in the production of the solar battery device 10.

An electronic device according to the present embodiment comprises or is electrically connectable with the solar battery device 10, the solar battery device 10 being located such that it is capable of receiving light.

As described above, the present invention provides a solar battery device, a method of producing the same, and an electronic device comprising the same, by each of which the reduction in power generation efficiency due to a surface protector or the like provided on the surface of the solar battery device is prevented, and which has or provides excellent transportability and applicability to portable devices.

The solar battery device 10 is preferably arranged such that the synthetic resin is a thermosetting resin, or that the synthetic resin is a thermoplastic resin containing a cross linking agent for causing cross-linking at heat application.

With this arrangement, in which the synthetic resin is one that is solidified at a high temperature, the synthetic resin (i.e., the surface protector 4) is hardly deformed in a situation in which the surface temperature of the solar battery device becomes high, e.g., in summer times.

The solar battery device 10 according to the present embodiment is preferably arranged such that the synthetic resin contains a filler by 50% or less by weight with respect to a total weight of the synthetic resin, the filler being made from a transparent material and having such a glass transition temperature that the filler will not be fluidized at a temperature at which flow molding of the synthetic resin is performed.

With this arrangement, the addition of the filler to the synthetic resin makes it easier to shape the synthetic resin. because the filler has such a glass transition temperature that the filler will not be fluidized at a temperature at which flow molding of the synthetic resin is performed, light reflection due to the filler is difficult to occur. Thus, the use of such a filler is preferable for solar battery devices. Moreover, the addition of filler prevents thermal deformation of the synthetic resin, and expansion/shrinkage of the synthetic resin. As to the filler content, the filler is contained in the synthetic resin by 10%, 30%, or 50% by weight with respect to the total weight of the synthetic resin in general.

The solar battery device 10 according to the present embodiment is preferably arranged such that the synthetic resin is colored.

This arrangement provides the solar battery device with a beautiful appearance, thereby giving a greater commercial value to the solar battery device. Instead of coloring the synthetic resin, a colored cover may be provided on the synthetic resin.

The solar battery device 10 according to the present embodiment is preferably arranged such that the anti-reflection process 5 matt-finishes the incident surface. The solar battery device 10 according to the present embodiment is preferably arranged such that matt-finishing gives the incident surface a central line surface roughness Ra in a range of 0.03 μm to 2.00 μm.

With this arrangement, the matt-finishing gives the incident surface the matt-finished shape and the central line surface roughness Ra in a range of 0.03 μm to 2.00 μm. As a result, a high anti-reflection effect is expected. A central line surface roughness Ra of less than 0.03 μm means that the surface is flat, meanwhile a central line surface roughness Ra of more than 2.00 μm means the matt-finished shape has too large protrusions to cause the anti-reflection effect.

The electronic device according to the present embodiment is preferably a portable telephone, a digital still camera, a digital video camera, a portable game machine, or a GPS device.

The method according to the present embodiment is preferably arranged such that the step (iii) is carried out by using a die.

In case where the anti-reflection process 5 is carried out by rubbing, polishing, etc., it will produce shavings, which would possibly produce a problem such as deterioration in power generation efficiency of the solar battery device. Therefore, it is preferable to carry out the anti-reflection process 5 by using a die, which will not produce shavings.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

A solar battery device according to the present invention is such that reduction in power generation efficiency due to a surface protector or the like provided on the surface of the solar battery device is prevented, and that has excellent transportability and applicability to portable devices. For example, the solar battery device according to the present invention is preferably applicable to an electronic device (portable electronic device) such as a portable telephone, digital still camera, digital video camera, portable game machine, a GPS device, or the like. Moreover, the method according to the present invention is preferably applicable to production of a solar battery device and can provide the solar battery device excellent transportability and applicability to portable devices, while preventing the reduction in power generation efficiency due to the surface protector or the like provided on the surface of the solar battery device.

### REFERENCE SIGNS LIST

1 Solar Cell
2 Support Substrate (Substrate)
4 Surface Protector
5 Anti-Reflection. Process
10 Solar Battery Device
Ra Central Line Surface Roughness

1. A solar battery device, comprising:
a substrate;
at least one solar cell on the substrate;
a surface protector on the solar cell, so as to protect a surface of the solar battery device,
the surface protector being made of a synthetic resin, and having an incident surface to which light enters, and which is subjected to an anti-reflection process for preventing reflection of the light.

2. The solar battery device as set forth in claim 1, wherein the synthetic resin is a thermosetting resin.

3. The solar battery device as set forth in claim 1, wherein the synthetic resin is a thermoplastic resin containing a cross linking agent for causing cross-linking at heat application.

4. The solar battery device as set forth claim 1, wherein:
the synthetic resin contains a filler by 50% or less by weight with respect to a total weight of the synthetic resin, the filler being made from a transparent material and having such a glass transition temperature that the filler will not be fluidized at a temperature at which flow molding of the synthetic resin is performed.

5. The solar battery device as set forth in claim 1, wherein the synthetic resin is colored.

6. The solar battery device as set forth in claim 1, wherein the anti-reflection process matt-finishes the incident surface.

7. The solar battery device as set forth in claim 6, wherein the matt-finishing gives the incident surface a central line surface roughness in a range of 0.03 μm to 2.00 μm.

8. An electronic device comprising or being electrically connectable with a solar battery device as set forth in claim the solar battery device being located such that it is capable of receiving light.

9. The electronic device as set forth in claim 8, being a portable telephone, a digital still camera, a digital video camera, a portable game machine, or a GPS device.

10. A method for producing a solar battery device, the method comprising:
(i) forming at least one solar cell on a substrate;
(ii) forming a surface protector on the solar cell from a synthetic resin, the surface protector protecting a surface of the solar battery device; and
(iii) performing anti-reflection process on an incident surface of the surface protector to which incident surface light enters, the anti-reflection process preventing reflection of the light,
the step (ii) and step (iii) being carried out at a same time.

11. The method as set forth in claim 10 wherein the step is carried out by using a die.
